(19) United States
(12) Patent Application Publication
(10) Pub. No.: US 2024/0241922 A1
(43) Pub. Date: Jul. 18, 2024

(54) FEATURE CALCULATION DEVICE, FEATURE CALCULATION METHOD, AND FEATURE CALCULATION PROGRAM

(71) Applicant: NIPPON TELEGRAPH AND TELEPHONE CORPORATION, Tokyo (JP)

(72) Inventors: Bo HU, Musashino-shi, Tokyo (JP); Kazunori KAMIYA, Musashino-shi, Tokyo (JP)

(73) Assignee: NIPPON TELEGRAPH AND TELEPHONE CORPORATION, Tokyo (JP)

(21) Appl. No.: 18/290,033

(22) PCT Filed: May 14, 2021
(86) PCT No.: PCT/JP2021/018349

§ 371 Date: Nov. 9, 2023

(51) Int. Cl. G06F 18/2134; G06F 18/20

(52) U.S. Cl. CPC G06F 18/2134; G06F 18/29

(57) ABSTRACT

A generation unit is configured to generate a graph representing inter-node communication using information on communication between nodes on a network. A selection unit is configured to select a node satisfying a predetermined condition among nodes in the generated graph. A calculation unit is configured to calculate a feature value in the graph for the selected node by a predetermined learning method. An estimation unit is configured to estimate a feature value for a node other than the selected nodes by combining feature values estimated for sequentially adjacent nodes in the graph.

### TECHNICAL FIELD

The present invention relates to a feature value calculation device, a feature value calculation method and a feature value calculation program.

### BACKGROUND ART

There is demand for a technology of detecting a structure in a network called a “botnet”, consisting of “zombie computers” compromised by malware. A feature value of a graph with an IP host as a node and end-to-end communication between IP hosts as an edge is useful information for detecting the botnet structure.

Graph embedding is a well-known method that enables high-quality learning of feature values of a graph. For example, graph embeddings such as DeepWalk and Node2Vec can extract relevant nodes at several hops in the graph by learning feature vectors such that relevant nodes become similar to each other in low-dimensional feature value spaces (see Non Patent Literature 1).

### CITATION LIST

### Non Patent Literature

Non Patent Literature 1: Bryan Perozzi et al., “DeepWalk: Online Learning of Social Representations”, KDD '14, Proceedings of the 20th ACM SIGKDD international conference on Knowledge discovery, 2014

### SUMMARY OF INVENTION

### Technical Problem

However, the conventional methods have drawbacks that temporal and spatial calculation loads increase depending on the number of nodes.

The present invention is intended to solve the problem stated above, and an object of the present invention is to calculate a feature value from a graph representing a communication network with reduced temporal and spatial calculation loads.

### Solution to Problem

To solve the problem and achieve the object, a feature value calculation device according to the present invention includes: a generation unit configured to generate a graph representing inter-node communication using information on communication between nodes on a network; a selection unit configured to select a node satisfying a predetermined condition among nodes in the generated graph; a calculation unit configured to calculate a feature value in the graph for the selected node by a predetermined learning method; and an estimation unit configured to estimate a feature value for a node other than the selected nodes by combining feature values calculated for sequentially adjacent nodes in the graph.

### Advantageous Effects of Invention

According to the present invention, it is possible to calculate a feature value from a graph representing a communication network with reduced temporal and spatial calculation loads.

### BRIEF DESCRIPTION OF DRAWINGS

FIG. 1 is a schematic diagram illustrating an exemplified schematic configuration of a feature value calculation device.

FIG. 2 is a diagram illustrating processing of the feature value calculation device.

FIG. 3 is a diagram illustrating processing of the feature value calculation device.

FIG. 4 is a diagram illustrating processing of the feature value calculation device.

FIG. 5 is a flowchart illustrating a feature value calculation processing procedure.

FIG. 6 is a diagram illustrating a computer executing a feature value calculation program.

### DESCRIPTION OF EMBODIMENTS

One embodiment of the present invention will be described with reference to drawings hereinbelow. The present invention is not limited to this embodiment. The same components will be denoted by the same reference numerals in the description of drawings.

### [Configuration of Feature Value Calculation Device]

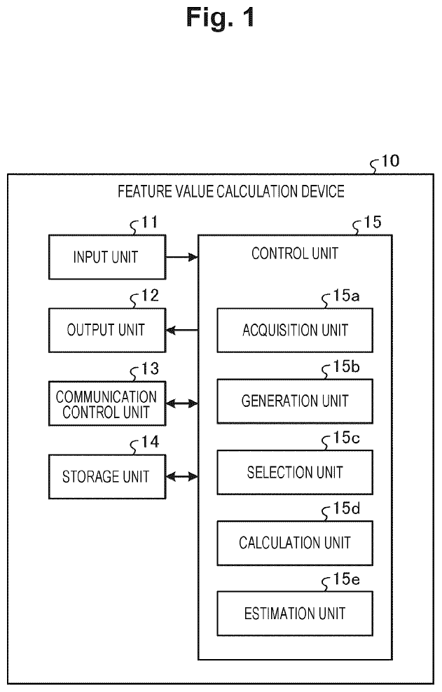

FIG. 1 is a schematic diagram illustrating an exemplified schematic configuration of a feature value calculation device. As illustrated in FIG. 1, a feature value calculation device 10 is implemented by a general-purpose computer, such as a personal computer, and includes an input unit 11, an output unit 12, a communication control unit 13, a storage unit 14, and a control unit 15.

The input unit 11 is implemented by using input devices such as a keyboard and a mouse, and inputs various kinds of instruction information such as a processing start to the control unit 15 in response to an input operation from an operator. The output unit 12 is implemented by a display device (e.g. liquid crystal display) or a printing device (e.g. printer).

The communication control unit 13 is implemented by, for example, a network interface card (NIC) and controls communication between an external device such as a server and the control unit 15 via a network. For example, the communication control unit 13 controls communication between the control unit 15 and a management device for collecting and managing network communication information.

The storage unit 14 is implemented by a semiconductor memory element such as a random access memory (RAM) or a flash memory, or a storage device such as a hard disk or an optical disc. In the storage unit 14, a processing program for operating the feature value calculation device 10, and data to be used during execution of the processing program are stored in advance or temporarily stored each time processing is performed. For example, the storage unit 14 stores an estimation model which is the processing result of the estimation unit to be described later. The storage unit 14 may be configured to establish communication with the control unit 15 via the communication control unit 13.

The control unit 15 is implemented by, for example, a central processing unit (CPU), and executes a processing program stored in a memory. As illustrated in FIG. 1, the control unit 15 functions as an acquisition unit 15a, a generation unit 15b, a selection unit 15c, a calculation unit 15d, and an estimation unit 15e. Each or some of these functional units may be provided in different hardware. For example, the calculation unit 15d and the estimation unit 15e may be implemented in different hardware. The control unit 15 may include other functional units.

The acquisition unit 15a acquires the collected communication information of nodes in the network. For example, the acquisition unit 15a acquires flow information of an IP host to be subject to feature value calculation processing described later from the management device for collecting and managing network communication information via the input unit 11 or the communication control unit 13. The acquisition unit 15a may store the acquired data in the storage unit 14. Alternatively, the acquisition unit 15a may transfer such information to the generation unit 15b described below instead of storing the information in the storage unit 14.

The generation unit 15b generates a graph representing inter-node communication using information on communication between nodes on the network. In particular, the generation unit 15b generates, using the acquired flow information of the IP host, a graph with the IP host as a node and communication between the IP hosts as an edge. At this time, the generation unit 15b generates a graph excluding nodes whose number of adjacent nodes is smaller than a predetermined threshold.

The selection unit 15c selects a node satisfying a predetermined condition among nodes in the generated graph. For example, the selection unit 15c selects a predetermined number of nodes in descending order of the number of adjacent nodes.

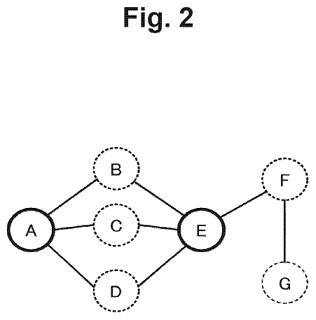

Alternatively, the selection unit 15c selects a node with a predetermined color in accordance with a coloring algorithm for applying colors to all nodes such that adjacent nodes have different colors. FIG. 2 is a diagram illustrating processing of the selection unit. As illustrated in FIG. 2, the selection unit 15c gives a color to each node such that each node has a color different from the adjacent node, for example, using Greedy Coloring algorithm. In the example illustrated in FIG. 2, nodes are selected in descending order of the number of adjacent nodes, and colors different from those of the adjacent nodes are assigned in a predetermined order, for example, red for nodes E and A, and blue for nodes B, C, and D. The selection unit 15c selects, for example, a node to which red is given (in the example of FIG. 2, the nodes A and E).

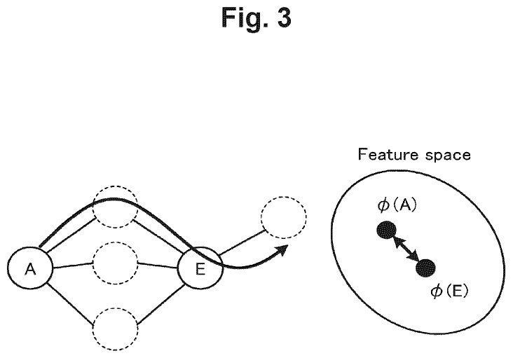

The calculation unit 15d calculates a feature value in the graph for the selected node by a predetermined learning method. FIG. 3 is a diagram illustrating processing of the calculation unit. As illustrated in FIG. 3, for example, the calculation unit 15d generates a path (list) including a plurality of nodes for each node by Random Walk on the graph, and calculates a feature value only for a selected node on the path by Word2Vec algorithm used also in DeepWalk.

In the example illustrated in FIG. 3, feature values ϕ (A) and ϕ (E) are calculated in a feature value space for the selected nodes A and E on the path. Accordingly, the calculation unit 15d calculates a feature value of the selected node only by a predetermined learning method without learning feature values for all the nodes as in DeepWalk.

The estimation unit 15e estimates a feature value for a node other than the selected nodes by combining feature values calculated for sequentially adjacent nodes in the graph. The “sequentially adjacent nodes” include an adjacent node of each node, and a secondary adjacent node next to the adjacent node.

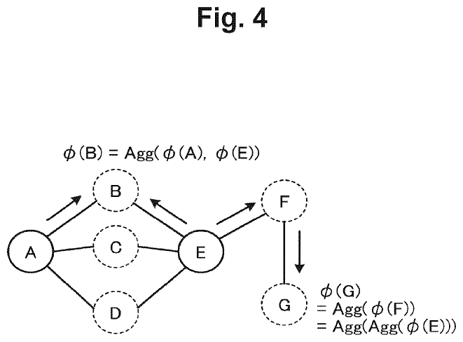

FIG. 4 is a diagram illustrating processing of the estimation unit. As illustrated in FIG. 4, the estimation unit 15e estimates a feature value for, for example, a node other than the selected nodes by combining feature values calculated for all selected nodes at a shortest distance from the node. Moreover, the estimation unit 15e estimates a feature value of a node other than the selected nodes with an average or Hadamard product for feature value vectors of a plurality of nodes.

In the example illustrated in FIG. 4, the estimation unit 15e calculates a feature value ϕ (B) of the untrained node B other than the selected nodes A and E with an average Agg (ϕ(A), ϕ(E)) of the feature value ϕ(A) of the node A and the feature value ϕ (E) of the node E. The estimation unit 15e also estimates a feature value ϕ (G) of the untrained node G with an average Agg (ϕ(F)) of feature values ϕ (F) of the nodes F, which are all nodes at the shortest distance, that is, the average Agg (Agg (ϕ(E))) of feature values ϕ (E) of the selected learned nodes E at the shortest distance of the nodes F.

Furthermore, the estimation unit 15e outputs the calculated feature value and the estimated feature value via the output unit 12.

### [Feature Value Calculation Processing]

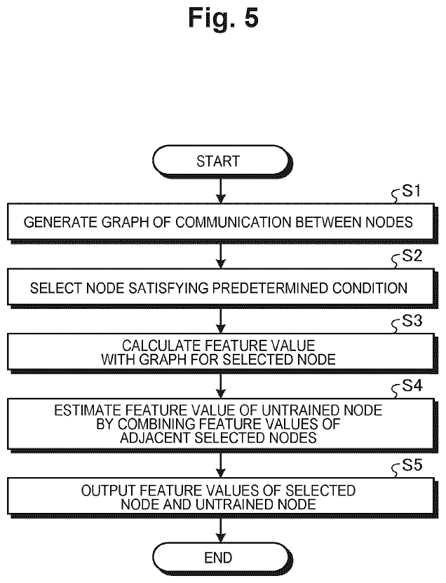

Referring to FIG. 5, feature value calculation processing executed by the feature value calculation device 10 according to the present embodiment will be described. FIG. 5 is a flowchart illustrating a feature value calculation processing procedure. The flowchart shown in FIG. 5 is initiated, for example, at a timing at which an operation for giving an instruction for starting the feature value calculation processing is input.

The generation unit 15b generates a graph representing inter-node communication using information on communication between nodes on the network, which is acquired by the acquisition unit 15a (step S1).

The selection unit 15c selects a node satisfying a predetermined condition among nodes in the generated graph (step S2). For example, the selection unit 15c selects a predetermined number of nodes in descending order of the number of adjacent nodes. Alternatively, the selection unit 15c selects a node which is given a predetermined color in accordance with a coloring algorithm.

The calculation unit 15d calculates a feature value in the graph for the selected node by a predetermined learning method (step S3).

The estimation unit 15e estimates a feature value for an untrained node other than the selected nodes by combining feature values calculated for adjacent selected nodes in the graph (step S4).

For example, the estimation unit 15e estimates a feature value for an untrained node other than the selected nodes by combining feature values calculated for all selected nodes at a shortest distance from the untrained node. At this time, the estimation unit 15e estimates a feature value of an untrained node other than the selected nodes with an average or Hadamard product for feature value vectors of a plurality of nodes.

The estimation unit 15e outputs the calculated feature value and the estimated feature value via the output unit 12 (step S5). Consequently, a series of feature value calculation processing end.

As described above, the generation unit 15b generates a graph representing inter-node communication using information on communication between nodes on the network in the feature value calculation device 10. The selection unit 15c selects a node satisfying a predetermined condition among nodes in the generated graph. The calculation unit 15d calculates a feature value in the graph for the selected node by a predetermined learning method. The estimation unit 15e estimates a feature value for a node other than the selected nodes by combining feature values calculated for sequentially adjacent nodes in the graph.

As described above, the feature value calculation device 10 reduces the calculation load by limiting calculations to those for the selected nodes at the time of learning. Accordingly, it is possible to calculate a feature value from a graph representing a communication network with reduced temporal and spatial calculation loads.

The generation unit 15b generates a graph excluding nodes whose number of adjacent nodes is smaller than a predetermined threshold. Consequently, the feature value calculation device 10 can efficiently calculate feature values.

The selection unit 15c selects a predetermined number of nodes in descending order of the number of adjacent nodes. Consequently, the feature value calculation device 10 can efficiently calculate feature values.

The selection unit 15c selects a node with a predetermined color in accordance with a coloring algorithm for applying colors to all nodes such that adjacent nodes have different colors. Consequently, the feature value calculation device 10 can efficiently calculate feature values.

The estimation unit 15e estimates a feature value for a node other than the selected nodes by combining feature values calculated for all selected nodes at a shortest distance from the node. Consequently, the feature value calculation device 10 can calculate feature values with high accuracy.

Moreover, the estimation unit 15e estimates a feature value of a node other than the selected nodes with an average or Hadamard product for feature value vectors of a plurality of nodes. Consequently, the feature value calculation device 10 can efficiently calculate feature values.

### [Program]

It is also possible to produce a program that describes, in a computer executable language, the processing executed by the feature value calculation device 10 according to the embodiment stated above. As one embodiment, the feature value calculation device 10 can be implemented by installing a feature value calculation program for executing the feature value calculation processing described above as package software or online software in a desired computer. For example, an information processing device can serve as the feature value calculation device 10 by causing the information processing device to execute the feature value calculation program above. The information processing device also includes a mobile communication terminal such as a smartphone, a mobile phone, and a personal handyphone system (PHS), and a slate terminal such as a personal digital assistant (PDA). The functions of the feature value calculation device 10 may be implemented in a cloud server.

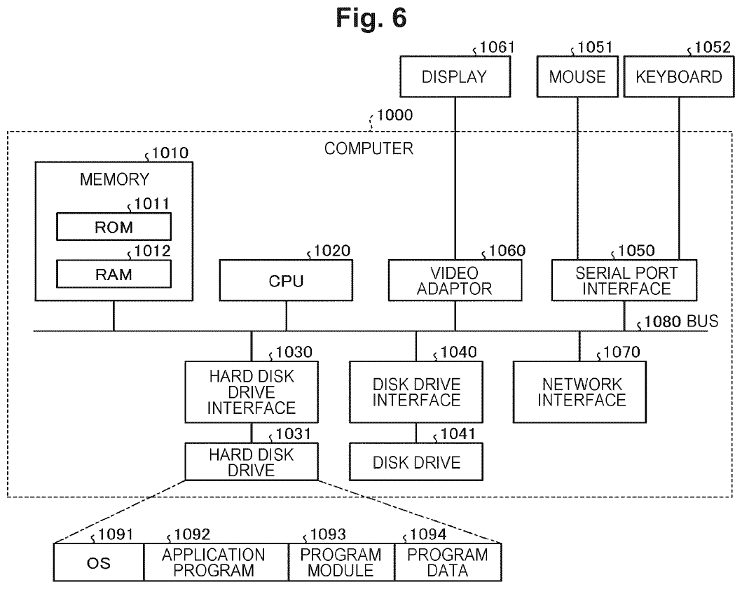

FIG. 6 is a diagram illustrating one example of the computer that executes the feature value calculation program. A computer 1000 includes, for example, a memory 1010, a CPU 1020, a hard disk drive interface 1030, a disk drive interface 1040, a serial port interface 1050, a video adapter 1060, and a network interface 1070. These units are connected to each other by a bus 1080.

The memory 1010 includes a read only memory (ROM) 1011 and a RAM 1012. The ROM 1011 stores, for example, a boot program such as a basic input output system (BIOS). The hard disk drive interface 1030 is connected to a hard disk drive 1031. The disk drive interface 1040 is connected to a disk drive 1041. For example, a removable storage medium such as a magnetic disk or an optical disc is inserted into the disk drive 1041. The serial port interface 1050 is connected to, for example, a mouse 1051 and a keyboard 1052. The video adapter 1060 is connected to, for example, a display 1061.

The hard disk drive 1031 stores, for example, an OS 1091, an application program 1092, a program module 1093, and program data 1094. All pieces of information described in the embodiment is stored in the hard disk drive 1031 or the memory 1010, for example.

The feature value calculation program is stored in the hard disk drive 1031 as the program module 1093 in which commands to be executed by the computer 1000, for example, are described. In particular, the program module 1093 in which each piece of the processing executed by the feature value calculation device 10 described in the embodiment above is described is stored in the hard disk drive 1031.

Data used for information processing executed by the feature value calculation program is stored as the program data 1094 in the hard disk drive 1031, for example. The CPU 1020 reads, into the RAM 1012, the program module 1093 and the program data 1094 stored in the hard disk drive 1031 as needed and executes each procedure described above.

The program module 1093 and the program data 1094 related to the feature value calculation program are not limited to being stored in the hard disk drive 1031, and may be stored in, for example, a removable storage medium and read by the CPU 1020 via the disk drive 1041 or the like. Alternatively, the program module 1093 and the program data 1094 related to the feature value calculation program may be stored in another computer connected via a network such as a local area network (LAN) or a wide area network (WAN) and may be read by the CPU 1020 via the network interface 1070.

Although the embodiments to which the invention made by the inventors is applied have been described above, the present invention is not limited to the description and the drawings showing a part of the disclosure of the present invention according to the present embodiment. In other words, other embodiments, examples and operation techniques made by those skilled in the art based on the present embodiment are all included in the scope of the present invention.

### REFERENCE SIGNS LIST

10 Feature value calculation device
11 Input unit
12 Output unit
13 Communication control unit
14 Storage unit
15 Control unit
15a Acquisition unit
15b Generation unit
15c Selection unit
15d Calculation unit
15e Estimation unit

1. A feature value calculation device comprising:
a memory; and
a processor coupled to the memory and programmed to execute a process comprising:
generating a graph representing inter-node communication using information on communication between nodes on a network:
selecting a node satisfying a predetermined condition among nodes in the generated graph;
calculating a feature value in the graph for the selected node by a predetermined learning method; and
estimating a feature value for a node other than the selected nodes by combining feature values calculated for sequentially adjacent nodes in the graph.

2. The feature value calculation device according to claim 1, wherein the generating a graph excluding nodes whose number of adjacent nodes is smaller than a predetermined threshold.

3. The feature value calculation device according to claim 1, wherein the selecting a predetermined number of nodes in descending order of the number of adjacent nodes.

4. The feature value calculation device according to claim 1, wherein the selecting a node with a predetermined color in accordance with a coloring algorithm for applying colors to all nodes such that adjacent nodes have different colors.

5. The feature value calculation device according to claim 1, wherein the estimating a feature value for a node other than the selected nodes by combining feature values calculated for all selected nodes at a shortest distance from the node.

6. The feature value calculation device according to claim 1, wherein the estimating a feature value of a node other than the selected nodes by an average or Hadamard product for feature value vectors of a plurality of nodes.

7. A feature value calculation method, executed by a feature value calculation device, the method comprising the steps of:
generating a graph representing inter-node communication using information on communication between nodes on a network;
selecting a node satisfying a predetermined condition among nodes in the generated graph;
calculating a feature value in the graph for the selected node by a predetermined learning method; and
estimating a feature value for a node other than the selected nodes by combining feature values calculated for sequentially adjacent nodes in the graph.

8. A non-transitory computer-readable recording medium having stored a feature value calculation program causing a computer to execute the steps of:
generating a graph representing inter-node communication using information on communication between nodes on a network;
selecting a node satisfying a predetermined condition among nodes in the generated graph;
calculating a feature value in the graph for the selected node by a predetermined learning method; and
estimating a feature value for a node other than the selected nodes by combining feature values calculated for sequentially adjacent nodes in the graph.
